(19) United States
(12) Patent Application Publication
(10) Pub. No.: US 2005/0022736 A1
(43) Pub. Date: Feb. 3, 2005

(54) Method for balancing return currents in plasma processing apparatus

(75) Inventor: Robert J. Steger, Los Altos, CA (US)

Correspondence Address: David B. Ritchie;Thelen Reid & Priest LLP, P.O. Box 640640, San Jose, CA, 95164-0640, US

(73) Assignee: Lam Research Inc., a Delaware Corporation

(21) Appl. No.: 10/630,584

(22) Filed: Jul. 29, 2003

(51) Int. Cl. C23C 16/00

(52) U.S. Cl. 118/715; 204/298.02

(57) ABSTRACT

A plasma processing reactor includes a chamber and a substrate support. The chamber includes an opening extending through a sidewall of the chamber. The substrate support is removably mounted within the chamber. The opening of the chamber is large enough to allow the substrate support to be removed from the chamber through the opening. A portion of a surface of the inner sidewall and the substrate support within the chamber has a coating. The coating is made of an electrically resistive material. The coating creates an impedance along the portion of the surface of the inner sidewall, which would otherwise carry a greater portion of the RF return current than the opposite side of the chamber. The coating also creates an impedance along the substrate support so that the density of the RF return current along the surface of the inner walls of the chamber is substantially more uniform.

### FIELD OF THE INVENTION

The present invention relates to equipment for processing substrates such as semiconductor wafers. More particularly, the present invention relates to a semiconductor processing apparatus generating plasma.

### BACKGROUND OF THE INVENTION

Gas plasmas are widely used in a variety of integrated circuit fabrication processes, including plasma etching and plasma deposition applications. Generally, gas plasmas are produced within a process chamber by introducing a low-pressure gas into the chamber and then directing electrical energy into the chamber for creating an electrical field. The electrical field creates an electron flow within the chamber which ionizes individual gas molecules by transferring kinetic energy through individual electron-gas molecule collisions. The electrons are accelerated within the electric field, producing efficient ionization of the gas molecules. The ionized particles of the gas and free electrons collectively form what is referred to as a gas plasma.

Gas plasmas are useful in a variety of different integrated circuit fabrication processes. One commonly used plasma process is a plasma etch process wherein a layer of material is removed or “etched” from a surface of a substrate. The ionized gas particles of the plasma are generally positively charged. Within an etching process, the substrate is negatively biased such that the positive ionized plasma particles are attracted to the substrate surface to bombard the surface and thereby etch the substrate surface.

Inductively coupled plasma etching systems may be used in the processing and fabrication of semiconductor devices. A shaped coil or antenna positioned with respect to the process chamber inductively couples energy into the chamber and thus creates and sustains a high-density plasma within the chamber. The Inductively coupled plasma etching system typically includes an RF power generator supplying RF power to the chuck within the plasma chamber.

However, the RF return current may not flow uniformly in the radial direction across the wafer being processed in some inductively coupled plasma etching systems. FIG. 1 illustrates an inductively coupled plasma etching system 100 in which the RF return current does not flow uniformly in the radial direction across the wafer being processed. A plasma chamber 102 houses an electrostatic chuck (ESC) 104 positioned on a support arm 106. An insulator 108 electrically insulates ESC 104 from support arm 106. The ESC 104 receives and supports a wafer 110 to be processed. A vacuum is maintained in the interior 120 of the chamber 102 by suitable vacuum pump 122 connected to a large outlet port 124 in an endwall such as the bottom chamber 102. A wafer transport 126 along a sidewall opposite to support arm 106 allows wafers to enter and leave the process chamber 102. The vacuum processing chamber 102 can be supplied with RF power through an external RF antenna such as a planar coil 128 outside a dielectric window 130. The dielectric window 130 serves as an endwall such as the top of the chamber 102.

The support arm 106 is removably mounted to the plasma chamber 102 through an opening in a sidewall of the plasma chamber 102. An RF power supply generator 114 supplies RF power to the ESC 104 through a matching network circuit 116. The incoming RF current generated by the RF power supply generator 114 passes through an RF feed rod 118. Because of the non-axis symmetric nature of the support arm 106, the RF return current to generator 114 is not axis symmetric, and has a minimum path length and maximum path length. The minimum return path of the RF current through the plasma and on the chamber inner wall is illustrated with arrows labeled “A”. The maximum return path of the RF current is illustrated with arrows labeled “B”. Because of non-axis symmetric nature of the return current paths, the etch rate pattern of the wafer may be non-uniform across the wafer.

Typically, the metallic elements, such as the wafer support arm 106 and the vacuum chamber 102, are made of aluminum alloys, which have fairly high electrical conductivity for low frequencies. The impedance of these metallic elements becomes increasingly important at higher frequencies. As such, when the RF return current path from the RF power generator 114 through the wafer 110 and back is not axially symmetric, the RF currents encounter higher impedance at some azimuthal location than at others, resulting in processing nonuniformities. Depending upon specific conditions, unacceptable nonuniformities in the processing can occur across the wafer surface.

In order to preserve consistent results of the plasma processing chamber, a need exists for a method and apparatus for balancing RF return currents so that the RF return currents on the wafer are made uniform so as to permit uniform processing. A primary purpose of the present invention is to solve these needs and provide further, related advantages.

### BRIEF DESCRIPTION OF THE INVENTION

A plasma processing reactor includes a chamber and a substrate support. The chamber includes an opening extending through a sidewall of the chamber. The substrate support is removably mounted within the chamber. The opening of the chamber is large enough to allow the substrate support to be removed from the chamber through the opening. A portion of a surface of the inner sidewall and the substrate support within the chamber has a coating. The coating is made of an electrically resistive material. The coating creates an impedance along the portion of the surface of the inner sidewall, which would otherwise carry a greater portion of the RF return current than the opposite side of the chamber. The coating also creates an impedance along the substrate support so that the density of the RF return current along the surface of the inner walls of the chamber is substantially more uniform.

### BRIEF DESCRIPTION OF THE DRAWINGS

The accompanying drawings, which are incorporated into and constitute a part of this specification, illustrate one or more embodiments of the present invention and, together with the detailed description, serve to explain the principles and implementations of the invention.

In the drawings:

FIG. 1 is a cross-sectional diagram schematically illustrating a plasma etching system in accordance with a prior art.

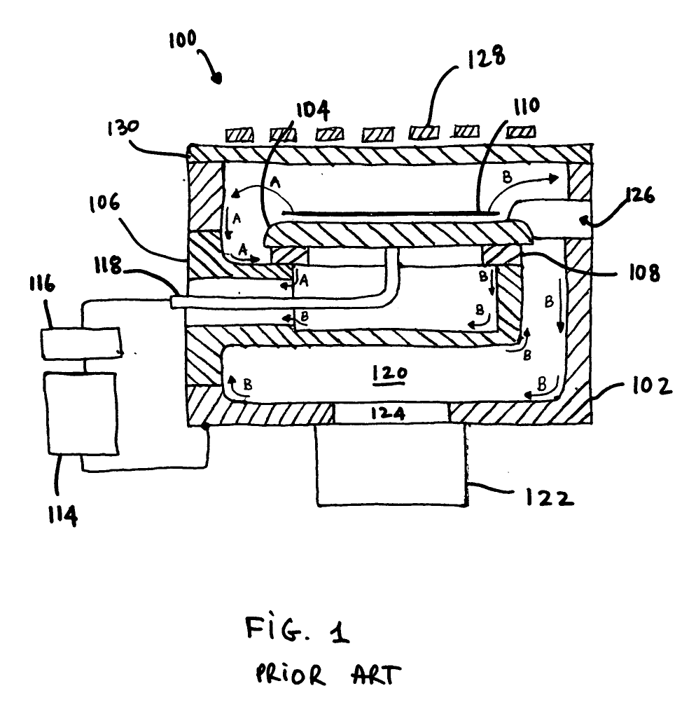

FIG. 2 is a cross-sectional diagram schematically illustrating a plasma etching system in accordance with one embodiment of the present invention.

FIG. 3 is a perspective schematic view of a substrate support of a plasma etching system in accordance with one embodiment of the present invention.

FIG. 4 is a perspective schematic view of a vacuum processing chamber of a plasma etching system without a substrate support and a top wall mounted plasma generating device in accordance with one embodiment of the present invention.

FIG. 5 is a flow diagram illustrating a method for balancing RF return currents in a plasma etching system in accordance with one embodiment of the present invention.

### DETAILED DESCRIPTION

Embodiments of the present invention are described herein in the context of a plasma etching system. Those of ordinary skill in the art will realize that the following detailed description of the present invention is illustrative only and is not intended to be in any way limiting. Other embodiments of the present invention will readily suggest themselves to such skilled persons having the benefit of this disclosure. Reference will now be made in detail to implementations of the present invention as illustrated in the accompanying drawings. The same reference indicators will be used throughout the drawings and the following detailed description to refer to the same or like parts.

In the interest of clarity, not all of the routine features of the implementations described herein are shown and described. It will, of course, be appreciated that in the development of any such actual implementation, numerous implementation-specific decisions must be made in order to achieve the developer's specific goals, such as compliance with application- and business-related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

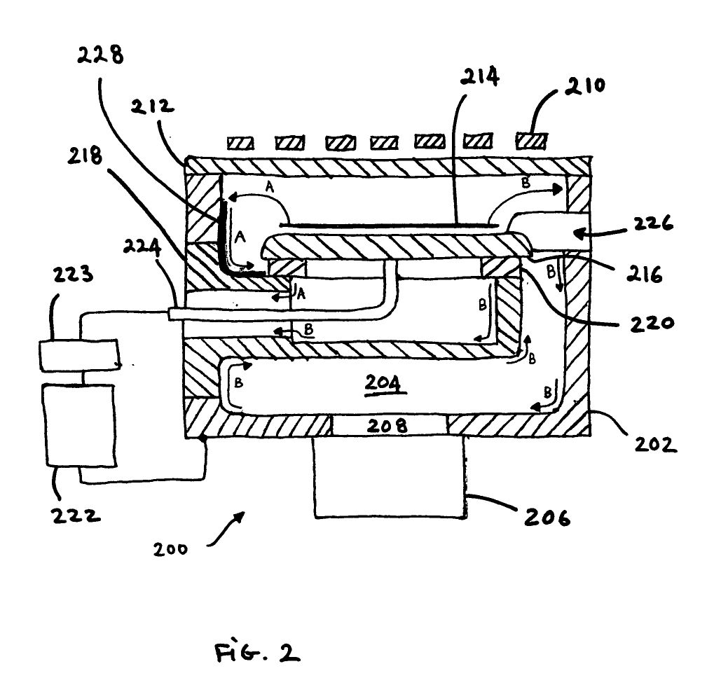

FIG. 2 illustrates a plasma processing system 200 in accordance with one embodiment of the present invention. The plasma processing system 200 may be used for various semiconductor plasma processing steps such as etching, deposition, resist stripping, etc. An example of a vacuum processing chamber 202 having an inductively coupled plasma source is shown in FIG. 2 wherein processing gas is supplied to the processing chamber 202 by suitable apparatus (not shown) such as gas distribution rings, gas distribution plate, injection nozzles, etc. A vacuum is maintained in the interior 204 of the chamber 202 by suitable vacuum pump apparatus 206 connected to a large outlet port 208 in an endwall such as the bottom of process chamber 202. The vacuum processing chamber 202 can be supplied with RF power through an external RF antenna such as a planar coil 210 outside a dielectric window 212. The dielectric window 212 may serve as an endwall such as the top of the chamber 202. However, the plasma generating source can be of any other type of plasma generating equipment such as that of an ECR reactor, parallel plate reactor, helicon reactor, helical resonator, etc.

A substrate 214 is supported within the chamber 202 on a substrate support 216 which is removably supported by a modular mounting arrangement such as the support arm 218 from a sidewall of the chamber 202. The substrate support 216 is at one end of a support arm 218 mounted in a cantilever fashion such that the entire substrate support/support arm assembly 216/218 can be removed from the chamber 202 by passing the assembly 216/218 through an opening in the sidewall of the chamber 202, as shown in FIG. 2. The substrate support 216 may include a chucking apparatus such as a mechanical ring clamp (not shown) and an RF biasing electrode (not shown) located in a central portion of the chamber below dielectric window 212. Alternatively, the chucking apparatus may comprise any suitable arrangement such as an electrostatic monopolar chuck of an electrically conductive material such as aluminum containing water cooling channels and grounded to a portion of the chamber or a multipolar chuck having electrically conductive electrodes covered with a layer of insulating material such as alumina.

The chucking arrangement according to the invention can be used in a plasma or non-plasma environment. Thus, while a specific embodiment of the invention is described below with reference to a chuck used to hold a semiconductor substrate in a plasma environment, the substrate support assembly 216/218 according to the invention can be used in other process chambers. Further, the chucking arrangement can incorporate (1) a mechanical clamp, (2) a monopolar ESC or a bipolar, multi-polar or flux-line ESC for holding semiconductor wafers or dielectric substrates in a plasma, non-plasma, vacuum or non-vacuum environment or (3) a monopolar ESC for holding dielectric substrates, such as glass panels used in making flat panel displays, in a plasma environment wherein the plasma is not used to supply ions to the substrate surface for purposes of clamping but rather, the plasma completes an electrical circuit between the monopolar ESC and a grounded surface such as part of the wall of the plasma processing chamber. Whether or not the ESC provides underside gas cooling of the substrate, the substrate may be temperature controlled by a water-cooled portion of the substrate support 216. The substrate support 216 can have a rectangular, square, circular or other shape suitable for clamping the particular substrate to be clamped.

An insulator 220 electrically insulates the substrate support 216 from support arm 218. An RF power supply generator 222 supplies RF power to the substrate support 216 through a matching network circuit 223. An electrical conduit 224, i.e. RF feed rod, couples the RF power supply generator 222 to the substrate support 216 via RF feeding rod 224. In accordance with one embodiment, the process chamber 202 also includes a wafer transport opening 226 along a sidewall opposite to the support arm 218. The wafer transport opening 226 allows wafers to enter and leave the process chamber 202.

FIG. 2 further illustrates the asymmetry of the RF return currents based on the geometry of the plasma chamber. The shorter RF return current path is illustrated by arrows A. The longer RF return current path is illustrated by arrows B. To balance the current densities around the plasma chamber, thin films 228 of materials having higher or lower resistivity than the base material (for example, in this case aluminum alloys) may be coated on portions of the surface of the inner walls of the plasma chamber 202. The thin films increase or decrease the impedance of the shorter RF return current path so as to balance the asymmetry resulting from the physical construction of the plasma chamber 202. The balance of the RF return currents along both the shorter and longer paths results in RF return currents being more uniform on the wafer 214 so as to permit a more uniform processing.

In accordance with one embodiment of the present invention, one way to even out the RF current density around the chamber is to vary the metal surface impedance along the inner sidewalls of the chamber 202 by applying a coating of higher or lower electrical resistivity (e.g. nickel plating, or copper plating) on select locations along the surface of the inner sidewalls of the chamber 202 affecting the shorter RF current return path.

The overall RF return currents around the chamber 202 may also be affected by the thickness of the film, the type of material of the film, and the placement and shape of the film. In accordance with one embodiment, the coating film may include a Nickel-plated layer having a thickness of about less than 0.003″ for a RF frequency of about 13.56 Mhz. Those skilled in the art will realize that the RF current flows in the surface of the metal, the so-called skin effect, and that embodiments using lower RF frequencies may utilize thicker films than those which employ higher RF frequencies. The coating may be applied on a region of a surface of the inner sidewall along the shorter return path so as to increase impedance. For example, the process chamber 202 may include coating 228 along the shorter return path of the RF current along an inner sidewall 228 of the support arm 218 as illustrated in FIG. 2. In accordance with another embodiment, the surface of the upper inner sidewall 230 within the process chamber 202 adjacent to the surface of the inner sidewall 228 of the support arm 218 may also be coated with the film. Alternatively, a coating could be applied to the longer path inner sidewalls if a lower impedance film was used.

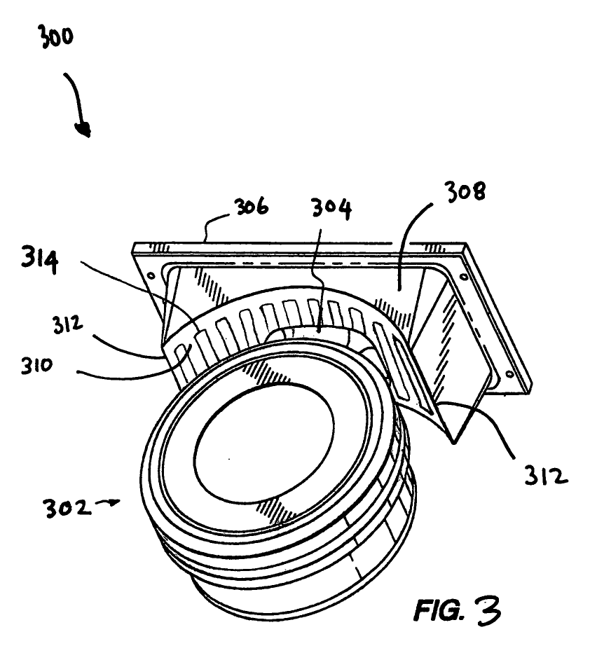

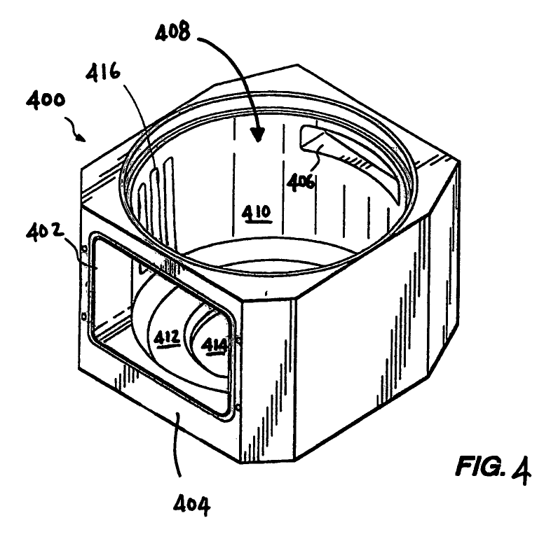

FIG. 3 is a perspective schematic view of a substrate support of a plasma etching system in accordance with one embodiment of the present invention. An example of a cantilevered chuck assembly 300 with the substrate support 302 is shown in FIG. 3. The assembly 300 includes a substrate support 302, a support arm 304 and a mounting flange 306. The mounting flange 306 includes a portion 308 which fits within opening 402 in sidewall 404 of the process chamber 400 as shown in FIG. 4. In the embodiment shown, one end of the support arm 304 joins an outer surface of the substrate support 302 and an opposite end of the support arm 304 joins the portion 308 of mounting flange 306. This arrangement can take various forms such as a one piece arrangement wherein the substrate support, the support arm and the flange are formed out of a single piece of material or a plurality of separate parts can be attached together to form the cantilever chuck assembly. The substrate support 302 may include a removable cap (not shown) having active components such as an ESC, RF biasing electrode or electrodes, lift pin holes, He backside cooling gas supply, etc.

As shown in FIG. 4, the chamber 400 includes a substrate transfer slot 406 through which a substrate such as a semiconductor wafer, flat panel, etc., can be transferred in a direction such as a horizontal direction by a suitable transfer mechanism into and out of the interior 408 of the chamber 400. In the embodiment shown, the interior 408 of the chamber 400 includes a cylindrical sidewall surface 410 and an annular bottom surface 412 surrounding the outlet port 414. The portion 308 of the mounting flange 306 includes a curved surface 310 having edges 312 which lie along edges of the opening 402 in the cylindrical sidewall surface 410 when the mounting flange 306 is mounted onto the exterior of the chamber 400. Support arm 304 includes an outer periphery offset vertically from the support surface of the substrate support 302. The support arm 304 supports the substrate support 302 in the interior 408 of the chamber 400 such that the outer periphery of the substrate support 302 is located inwardly of the cylindrical surface 410. Further, the portion 308 and the surfaces forming opening 402 may be tapered at an angle of no greater than 15 degrees.

The overall RF return currents travel along the surface of the inner sidewall 410 of the chamber 400 and along the curved surface 310 of the assembly 300. In accordance with one embodiment of the present invention, a plurality of filmstrips 314 may be coated at select locations on the curved surface 310 of the assembly 300 prior to the plasma etching process. Because of the geometry of the chamber 400, RF return currents may also be affected by the thickness of the filmstrips, the type of material of the filmstrips, and the placement and shape of the filmstrips. Continuous films may be employed as well as strips, and film thickness or resistivity may be altered locally to affect the impedance changes desired around the chamber inner sidewalls. In accordance with one embodiment, the coating film may include, for example, a Nickel-plated or Copper-plated layer having a thickness of about less than 0.003″. The coating may be selectively applied on the curved surface 310 of the assembly 300 along the shorter return path so as to increase impedance. For example, FIG. 3 illustrates a coating of several filmstrips 314 having a rectangular shape with the larger side perpendicular to the plane of the substrate support 302. The filmstrips 314 may have gaps between them to allow the RF return current to flow through. Those of ordinary skill in the art will appreciate that the filmstrips shown in FIG. 3 are not intended to be limiting and that other configurations can be used without departing from the inventive concepts herein disclosed. For examples, other thickness, type of material, and placement and shape of the filmstrips may be applied to create an impedance along the shorter return path that would render the RF return current path substantially more uniform around the chamber.

In accordance with another embodiment of the present invention, a coating of a film 314 having an impedance lower than the impedance of the underlying base material may be coated to the inner sidewall 410 of the chamber 400 along the “longer” RF return path B so as to decrease the impedance along that path.

In accordance with another embodiment of the present invention, a coating of a film 314 having an impedance higher than the impedance of the underlying base material may be coated to the inner sidewall 410 of the chamber 400 along the “shorter” RF return path A so as to increase the impedance along that path. For example, FIG. 4 illustrates a coating of several filmstrips 416 having a rectangular shape with the larger side perpendicular to the plane of the substrate support 302. The filmstrips 416 may have gaps between them to allow the RF return current to flow through.

In accordance with another embodiment of the present invention, filmstrips 314 may also be coated on portions of the surface of the support arm 304.

In accordance with another embodiment of the present invention, filmstrips 314 may also be coated on the outer surface of the support arm 304 (not shown).

The determination of the number and location of the film strips, film coatings on the chamber inner sidewall surface is necessarily experimental and iterative.

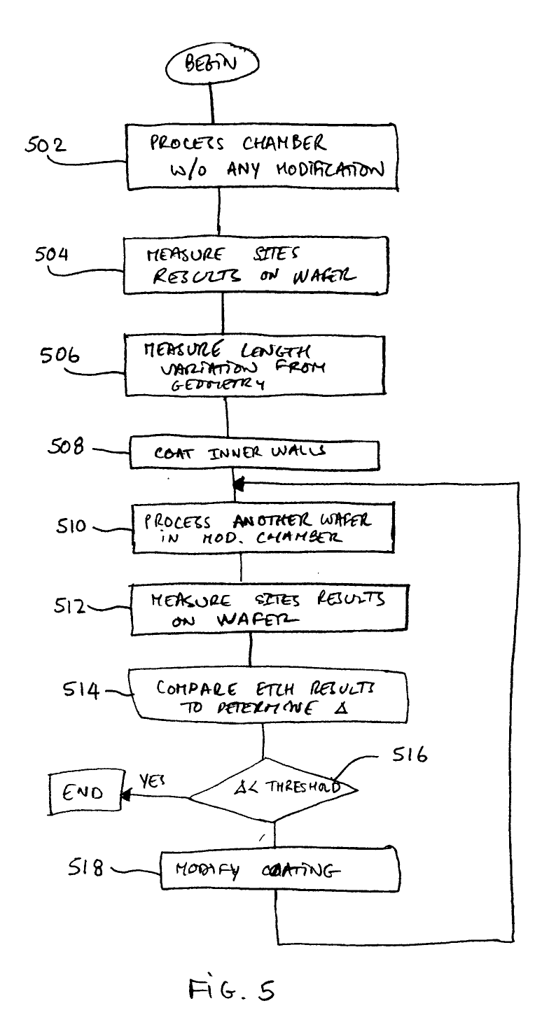

FIG. 5 illustrates a method of balancing RF return currents in a chamber having a geometry as described in FIGS. 2-4. At 502, a wafer is processed in a chamber having no modifications to the inner chamber sidewalls, to establish a baseline. At 504, etch rates and/or other performance measures are taken over the wafer surface and recorded. At 506, a first estimate of the RF current return path length variation around the chamber inner sidewall is made from an examination of the geometry of the chamber. At 508, the impedance along the shorter RF current return path is increased by the addition of strips of higher (relative to the base chamber material) resistivity coating around the inner chamber wall. In accordance with another embodiment of the present invention, the impedance along the longer RF current return path is decreased by the addition of strips of films of lower resistivity (relative to the underlying base material) coating around the inner chamber wall.

At 510, another wafer is processed under conditions identical to those employed in the baseline case. At 512, the newly processed wafer is measured in the same way and that data recorded. At 514, these additional data are subtracted site by site and a map showing the differences is examined at 516 to ascertain whether too much or too little impedance had been added, and whether the azimuthal distribution was lesser or greater than optimal. At 518, the chamber inner walls are then modified by adding or subtracting a coating of film or film strips, so as to further optimize the impedance distribution. The process reiterates at 510 with another wafer being processed as in the previous cases and a comparison made to the additional data set to determine if an optimal condition had been achieved.

It is known to those skilled in the art that there may be sources of azimuthal variation in wafer processing which are not caused by nonuniformities in RF return current, and that by careful data analysis and auxiliary experiments the source of such variations can be discerned from those caused by non-uniform RF current flows.

While embodiments and applications of this invention have been shown and described, it would be apparent to those skilled in the art having the benefit of this disclosure that many more modifications than mentioned above are possible without departing from the inventive concepts herein. The invention, therefore, is not to be restricted except in the spirit of the appended claims.

1. A plasma processing reactor comprising:
a chamber having a removable substrate support which is not axially symmetric about a vertical axis of said chamber;
a RF power supply coupled to said chamber, said RF power supply adapted to supply RF power to the interior of said chamber and thereby create a plasma therein;
a coating of a film selectively applied prior to a processing to a portion of a surface of an inner sidewall of said chamber, said coating including an electrically resistive material having an RF impedance substantially different from an underlying base material of said chamber.

2. The plasma processing reactor of claim 1 wherein said film is applied with varying composition around said inner sidewall of said chamber so as to vary the RF impedance azimuthally.

3. The plasma processing reactor of claim 1 wherein said film is applied with varying thickness around said inner sidewall of said chamber so as to vary the RF impedance azimuthally.

4. The plasma processing reactor of claim 1 wherein said film is in various shapes providing partial coverage around said inner sidewall of said chamber so as to vary the RF impedance azimuthally.

5. The plasma processing reactor of claim 1 wherein said coating includes a plurality of film strips which thickness varies along said portion of said surface of said sidewall and along said substrate support.

6. The plasma processing reactor of claim 1 wherein said coating includes a plurality of film strips azimuthally positioned.

7. The plasma processing reactor of claim 1 further comprising said coating of said film selectively applied prior to said processing to a portion of a surface of said removable substrate support within said chamber.

8. The plasma processing reactor of claim 1 wherein said electrically resistive material includes Nickel.

9. The plasma processing reactor of claim 1 wherein said electrically resistive material includes Copper.

10. The plasma processing reactor of claim 1 wherein said coating is plated to said portion of said surface of said inner sidewall of said chamber.

11. A plasma processing reactor comprising:
a chamber including an opening extending through an inner sidewall of said chamber;
a substrate support removably mounted therein, said opening large enough to allow said substrate support to be removed from said chamber through said opening;
a coating of a plurality of film strips applied to a portion of a surface of said inner sidewall and said substrate support within said chamber, said coating including an electrically resistive material having an RF impedance substantially different from the underlying base material of said chamber.

12. A method for balancing return currents in a plasma processing reactor having a chamber including an opening extending through an inner sidewall of said chamber, a substrate support removably mounted therein, the opening large enough to allow the substrate support to be removed from the chamber through the opening, the method comprising:
selectively applying a coating of a film to a portion of a surface of the inner walls of said chamber, said coating including an electrically resistive material having an RF impedance substantially different from an underlying base material of said chamber.

13. The method of claim 12 further comprising selectively applying said coating of said film to a portion of a surface of the substrate support within said chamber.

14. The method of claim 12 wherein said applying said coating of said film further comprises plating said coating of said film.

15. The method of claim 12 wherein said coating has a variable thickness.

16. The method of claim 12 wherein said electrically resistive material includes Nickel.

17. The method of claim 12 wherein said electrically resistive material includes Copper.

18. The method of claim 12 wherein said coating includes a plurality of film strips.

19. The method of claim 12 further comprising positioning said plurality of film strips vertically.

20. The method of claim 12 further comprising positioning said plurality of film strips horizontally.
